(19) United States
(12) Patent Application Publication
(10) Pub. No.: US 2008/0031051 A1
(43) Pub. Date: Feb. 7, 2008

(54) Memory device and method for programming a nonvolatile memory matrix

(76) Inventor: Arno Soerensen, Muenchen (DE)

Correspondence Address: MG-IP Law, PLLC, P.O. BOX 1364, FAIRFAX, VA, 22038-1364, US

(21) Appl. No.: 11/802,237

(22) Filed: May 21, 2007

Related U.S. Application Data
(60) Provisional application No. 60/801,403, filed on May 19, 2006.

(30) Foreign Application Priority Data
May 19, 2006 (DE) DE 102006023933

(51) Int. Cl. G11C 11/34

(52) U.S. Cl. 365/185.23

(57) ABSTRACT

A memory device comprising a nonvolatile memory matrix (EEPROM), a driver for programming the memory matrix, which is connected to the memory matrix to drive a programming potential, a volatile signal memory to drive the driver and a changeable voltage source, which is connected to the volatile signal memory to adjust an output voltage of the volatile signal memory for programming the nonvolatile memory matrix (EEPROM).

This nonprovisional application claims priority to German Patent Application No. DE 102006023933, which was filed in Germany on May 19, 2006, and to U.S. Provisional Application No. 60/801,403, which was filed on May 19, 2006, and which are both herein incorporated by reference.

### BACKGROUND OF THE INVENTION

1. Field of the Invention

The present invention relates to a memory device and a method for programming a nonvolatile memory matrix, particularly an electrically erasable programmable read-only memory (EEPROM) matrix field or an electrically programmable read-only memory (EPROM) matrix field.

2. Description of the Background Art

Electrically erasable programmable read-only memories are abbreviated using the English abbreviation EEPROM or E²PROM. EEPROMs with use of hot carrier injection programming instead of Fowler-Nordheim tunneling programming are disclosed, for example, in U.S. Pat. No. 4,698,787 or in the German patent publication DE 695 22 738 T2, which corresponds to U.S. Pat. No. 5,412,603.

In a conventional method for programming memory cells, as in FIGS. 1 and 2, a high voltage is applied at the control gate by using hot channel techniques for programming a cell by hot carrier injection. During programming of a selected cell by hot carrier injection, the voltages applied at the source, drain, and control gate are: a reference voltage applied at the source, which is equal to the substrate voltage (VSS, which may be 0 V); a first positive voltage VBL applied at the drain, about +5 V to +7 V with respect to the reference voltage; and a second positive voltage VPP applied at the control gate with respect to the reference voltage.

Under these conditions, the channel between the drain and the source is highly conductive. Electrons, reaching the substrate-drain PN junction, are subjected to two electrical fields in the matrix (EEPROM), one associated with the reverse-biased substrate-drain PN junction and the other associated with the positive voltage between the control gate and the floating gate.

The electrical field generated in the silicon substrate near the substrate-drain PN junction and the floating-gate interface in the matrix is the main factor in determining programmability by hot carrier injection in floating gate memories, such as, for instance, EPROM and flash-EPROM matrix fields. The electrical field in the matrix depends primarily on the drain-source potential, but comprises other parameters as well, such as, for instance, the doping profile of the channel zone and the drain zone.

One type of floating-gate memory matrix field requires both a 5-volt voltage supply and a 12-volt voltage supply as supply potentials. In such dual-supply memories, the 12-volt voltage is used to furnish the +5 V to +7 V drain voltage VBL required during programming. Another type of floating-gate memory matrix field requires a single 5 V supply. In that single-supply memory, the 5-volt voltage supply is pumped by a charge pump circuit to furnish a drain voltage VBL during programming, which is greater than +6 V.

According to DE 695 22 738 T2, a charge pump circuit can be used to pump the source of a selected cell to a voltage less than the voltage at the reference terminal of the integrated memory circuit. At the same time, the drain potential of the selected cell is pumped to a voltage that is above the voltage at the memory supply voltage terminal.

For example, in DE 695 22 738 T2, a drain-source potential of about 6 V is achieved from a 3 V supply by using a charge pump circuit to pump the source voltage to about 1.5 V below the voltage at the reference terminal of this 3 V supply and, at the same time, to pump the drain voltage to 1.5 V above the voltage at the positive terminal of this 3 V supply. The charge pump circuit can also be used to pump the cell substrate voltage to a value near to or lower than the source voltage. For improved programming efficiency, the cell substrate voltage is pumped to a value less than the source voltage.

In FIG. 1, to illustrate the conventional art, a matrix field (EEPROM) of memory cells is shown, which are integrated into a memory component. Each cell is a transistor 10 having a source 11, a drain 12, a floating gate 13, and a control gate 14. Each control gate 14 in a row of cells 10 is connected to a wordline 15, and each wordline 15 is connected to a wordline decoder 16.

Each source 11 in a row of cells 10 is connected to a source line 17. Each drain 12 in a column of cells 10 is connected to a drain-column line 18. Each source line 17 is connected by a common-column line 17a to a column decoder 19 and each drain-column line 18 is connected to the column decoder 19.

In the read mode, wordline decoder 16 functions, in response to wordline address signals on lines 20R and to signals from read/write/erase control circuit 21—which may be a microprocessor, for example—to apply a preselected positive voltage VCC (approximately +5 V) to selected wordline 15, and to apply a low voltage (ground or VSS) to deselected wordlines 15.

Column decoder 19 functions to apply a preselected positive voltage VSEN (approximately +1 V) to at least the selected drain-column line 18 and to apply a low voltage (0 V) to the source line 17. Column decoder 19 also functions, in response to signals on address lines 20D, to connect the selected drain-column line 18 of selected cell 10 to data input/output terminal 22. The conductive or nonconductive state of cell 10, connected to the selected drain-column line 18 and the selected wordline 15, is detected by a sense amplifier (not shown in FIG. 1) connected to data input/data output terminal 22.

During the flash-erase mode, column decoder 19 may function to control all drain-column lines 18 floating (to connect to a high impedance such as, for instance, field-effect transistors biased in an “OFF” state). Wordline decoder 16 functions, for example, to connect all wordlines 15 to a negative voltage VEE (approximately −10 V or −13 V). Column decoder 19 also functions to apply a positive voltage VCC (approximately +5 V or +3 V) to all source lines 17.

The substrate isolation well W2 of FIG. 2 of DE 695 22 738 T2 is connected by substrate control circuit 23 to VSS or 0 V. Wordline decoder 16 functions to connect all wordlines 15 to a negative voltage VEE (approximately −9 V).

Column decoder 19 also functions to connect all source lines 17 and all drain lines 18 to +6 V. The substrate isolation well W2 is also connected to +6 V during this operation. These erasing voltages between the potentials create sufficient field strength across the gate oxide zone to generate a Fowler-Nordheim tunneling current that transfers charge from floating gate 13, erasing memory cell 10. Since the potential on wordline 15 is negative, cell 10 remains in the nonconducting state during the erase.

In the write or program mode in DE 695 22 738 T2, wordline decoder 16 may function, in response to wordline address signals on lines 20R and to signals from read/write/erase control circuit 21 to apply a preselected first programming potential VPP (approximately +12 V) at a selected wordline 15, including a selected control gate 14. Column decoder 19 also functions to apply a second programming voltage VBL (approximately +5 V to +10 V) at a selected drain-column line 18 and, therefore, at drain 12 of selected cell 10.

In the circuit of FIGS. 1 and 2 of this state of the art, source lines 17 are connected, for example, to reference potential VSS, which may be ground. All of the deselected drain-column lines 18 are connected to reference potential VSS or are made potential-free. The programming voltages because of these potential differences create a high current state (drain 12 to source 11) in the channel of the selected memory cell 10, resulting in the generation near the drain-channel junction of channel-hot electrons and avalanche-breakdown electrons that are injected across the channel oxide to floating gate 13 of the selected cell 10.

The programming time is selected to be sufficiently long to program floating gate 13 with a negative program charge of approximately −2 V to −6 V with respect to the channel zone (with the control gate 14 at 0 V). Therefore, the prior-art programming potential VPP of 12 V, for example, on a selected wordline 15, including the selected control gate 14, generates a potential of approximately +7.2 V at the selected floating gate 13.

The voltage between floating gate 13 (at approximately +7.2 V) and the grounded (approximately 0 V) source line 17 is insufficient to cause a Fowler-Nordheim tunneling current across the gate oxide between a source 11 and a floating gate 13 to charge floating gate 13 of a selected or deselected cell 10. Floating gate 13 of the selected cell 10 is charged with hot electrons injected during programming, and the electrons in turn render the source-drain path under floating gate 13 of selected cell 10 nonconductive with +5 V on its control gate 14, a state which is read as a “zero” bit. Non-programmed cells 10 have source-drain paths under the floating gate 13 that are conductive with +5 V on their control gates 14, and those cells 10 are read as “one” bits.

In the write or program operation according to the prior art in FIGS. 1 and 2, the drain-source potential required for programming is achieved by using a charge pump circuit to pump source 11 of the selected cell 10 to a potential VSL of about −1 V to −2 V below the potential VSS at the negative terminal of the supply (of perhaps 3 V) and, at the same time, to pump drain 12 of the selected cell 10 to a voltage VBL of about +6 V above the potential at the source.

At the same time, a substrate potential VSUB of a substrate isolation well W2 in substrate 24 is connected by substrate control circuit 23 to either potential VSUB, which may be the same potential VSL as source 11, or to a more negative potential value of about −2 V to −3 V below the voltage VSS at the negative terminal of the power supply. The substrate isolation well W2 must isolate at least each selected cell 10 or the entire memory cell matrix field.

Hot-carrier-injection programming of the selected cell 10 is achieved by applying a pulse of VPP of about +10 V at gate 14 of the selected cell 10. The deselected wordlines are connected to VSS or 0 V or to a potential of about −1 V to −2 V with respect to VSS to prevent deselected cells from leaking.

### SUMMARY OF THE INVENTION

It is therefore an object of the present invention to provide a memory device with as simplified a fabrication as possible.

Therefore, a memory device having a nonvolatile memory matrix is provided. This nonvolatile memory matrix is preferably an electrically erasable programmable read-only memory (abbreviated in English as: EEPROM) matrix or an electrically programmable read-only memory (abbreviated in English as: EPROM) matrix. The nonvolatile memory matrix thereby does not lose the stored data, when a supply voltage is disconnected.

The memory device preferably has a driver for programming the memory matrix. The driver functions to drive a programming potential and for this purpose is connected to the memory matrix. The driver is thereby designed for the currents and voltages necessary for programming, so that, for example, transistors, voltage-proof and/or current-proof relative to the programming potential, are used for the driver. The programming may require a positive programming potential or a negative programming potential depending on the employed memory cell structure. Advantageously, the memory device uses both a positive and a negative programming potential to apply their difference for programming to the cell of the nonvolatile memory matrix.

Furthermore, the memory device has a volatile signal memory to drive the driver. A volatile signal memory of this type loses the memory content in this case as soon as a sufficient supply voltage is no longer applied. The signal memory can preferably store bit values, which can be decoded by a decoder to program values into a row or column of the nonvolatile memory matrix.

The memory device furthermore can have a changeable voltage source. The changeable voltage source can supply changeable voltages or potentials. To accomplish the change, the voltages or potentials of the changeable voltage source can be, for example, continuously controllable or, for example, be switched. The changeable voltage source is connected to the volatile signal memory to adjust an output voltage of the volatile signal memory for programming the nonvolatile memory matrix.

According to an embodiment, the changeable voltage source is connected to a number of supply terminals of the signal memory. For example, the signal memory has a positive supply terminal and a negative supply terminal, both of which are connected to the changeable voltage source. Preferably, however, the signal memory has four supply terminals which are all connected to the voltage source. Advantageously, at least two potentials at two different supply terminals can be changed differently from one another. The changeable voltage source is advantageously connected to a number of supply terminals of the driver. In so doing, depending on the application, a supply terminal or a plurality of supply terminals is needed. Preferably, the voltage source outputs connected to the supply terminals of the driver supply a changeable voltage.

According to another embodiment of the invention, the volatile signal memory has a static memory, particularly a latch or a flip-flop. Depending on the size of the nonvolatile memory, the signal memory is advantageously equipped with an appropriate number of memory elements, such as static storage, latches, flip-flops, or the like. In a simple embodiment, the signal memory has two inverters with mutual feedback. If both a positive programming voltage and a negative programming voltage are used for programming the nonvolatile memory matrix, the signal memory for each incoming bit preferably has a first static memory for a positive branch and a second static memory for a negative branch, in which mutually dependent bit values are stored. The voltages at the supply terminals of the first static memory can thereby be set irrespective of the voltages at the supply terminals of the second static memory of the changeable voltage source.

According to an embodiment of the invention, the driver has a push-pull stage. The push-pull stage thereby has at least two complementary transistors, and one transistor of the complementary transistors is supplied with a programming potential. If both a positive programming potential and a negative programming potential are used for programming the nonvolatile memory matrix, a first transistor of the complementary transistors is connected to a first terminal of the positive programming potential and a second transistor of the complementary transistors to a second terminal of the negative programming potential.

According to an embodiment of the invention, a decoder is connected between the volatile signal memory and the driver. This decoder is advantageously designed as a multiplexer. The decoder enables the decoding of the information (bit values), stored in the volatile signal memory, on the rows and columns of the volatile memory matrix and conducts the particular bit value of the volatile signal memory to the driver, assigned by the decoding, of the row or column in the volatile memory matrix. It is also possible in principle to connect the volatile signal memory between the decoder and the driver. In this alternative case, the already decoded values for the rows and columns in the volatile memory matrix for programming are stored in the volatile signal memory.

It is preferably provided that the changeable voltage source is connected to a number of supply terminals of the decoder. The supply voltage applied at the decoder thereby approaches the logic voltage, so that simple logic transistors may be used. For this reason, it is not necessary to design the decoder for arising programming potentials. Advantageously, the supply potentials of the decoder and/or of the driver are changed depending on the supply potentials of the volatile signal memory by connecting the volatile signal memory, the decoder, and/or the driver to the same outputs of the changeable voltage source.

It is also preferably provided in this case that the changeable voltage source is connected to a first supply voltage terminal of the volatile signal memory to apply a first, changeable supply potential and to a second supply voltage terminal of the volatile signal memory to apply a second, changeable supply potential. Advantageously, the changeable voltage source is designed in such a way that the second, changeable supply potential differs by a fixed differential voltage from the first, changeable supply potential. This advantageously has the effect that the supply voltage of the. volatile signal memory remains substantially constant in time as the fixed difference of the two supply potentials irrespective of the time change in the two supply potentials. Advantageously, the differential voltage is a type of logic voltage provided on the semiconductor chip, so that the transistors of the static memory of the volatile signal memory with the same technology as that of a logic may be used.

The changeable voltage source can be connected to a third supply voltage terminal of the volatile signal memory to apply a third, changeable supply potential and to a fourth supply voltage terminal of the volatile signal memory to apply a fourth, changeable supply potential. The third and fourth supply potential is advantageously used when a negative programming potential is to be generated. In this case, a negative programming potential can also be used exclusively, so that in this case a first or second supply potential is not needed. Especially preferably, however, both a positive and a negative programming potential are used, so that advantageously all four supply potentials are controlled by the changeable voltage source. Advantageously, the changeable voltage source is designed in such a way that the fourth, changeable supply potential differs by a fixed differential voltage from the third, changeable supply potential.

Advantageously, the changeable voltage source applies the first supply potential and the third supply potential at the driver and/or at the decoder. The total programming voltage is advantageously formed by the potential difference between the first supply potential and the third supply potential.

According to an embodiment of the invention, the changeable voltage source has at least one controllable charge pump. Preferably, the changeable voltage source has a controllable charge pump for each supply potential, so that the changeable voltage source preferably has at least two controllable charge pumps with different pump voltages.

According to an embodiment, a means for limiting the current drain from the changeable voltage source is provided. This means, for example, has a resistor or a current source or a current limiting circuit.

To embody the invention further advantageously, it is provided that the means for limiting the current drain has two transistors, which are connected to a pulse-forming circuit for driving, and the pulse-forming circuit is designed in such a way that the two transistors are controlled exclusively for writing the volatile signal memory during a brief pulse in the conducting state.

The pulse-forming circuit is preferably connected to the inputs of the volatile signal memory. The pulse-forming circuit is advantageously designed as a pulse gate to generate a pulse from a bit value.

The first transistor of the signal memory transistors is connected for setting and the second transistor of the signal memory transistors for resetting a static memory of the signal memory. A first control input of the first transistor is here connected to a first input of the signal memory and a second control input of the second transistor is here connected to a second input of the signal memory.

The memory device can be designed and set up in such a way that the memory matrix is operated for programming both with the positive programming potential and with the negative programming potential; here, the positive programming potential is more positive than each logic potential and the negative programming potential more negative than each logic potential.

Furthermore, the object of the invention is to provide a method for programming a nonvolatile memory matrix.

Therefore, a method for programming a nonvolatile memory matrix is provided. In this case, the programming potential different from the logic potentials is applied for programming. The programming potential can be obtained advantageously by means of a charge pump from a logic potential.

For programming, a bit value that corresponds to a row or column of the memory matrix and is optionally to be decoded is read into a volatile signal memory as an H level or an L level.

The signal memory can be set or reset for this purpose by means of a short pulse to advantageously limit the current drain from a charge pump.

Accordingly, all supply potentials of the signal memory are increased by an offset voltage in such a way that the H level or the L level approaches the desired programming potential. For example, an H level effects the conduction by a transistor in a positive branch of a connected push-pull stage, which connects the necessary programming potential to a corresponding cell in the nonvolatile memory matrix. For reading, a current is impressed in the nonvolatile memory matrix. Depending on the voltage drop, a bit value is then read out of the nonvolatile memory matrix.

Instead of the specification of potentials, voltages can also be defined that relate to a fixed reference potential, for example, a ground potential.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram for a conventional memory matrix field,

FIG. 2 is a cross-section of a memory cell with a floating gate according to the conventional art,

FIG. 3a a first embodiment of a volatile signal memory with a flip-flop,

FIG. 3b a second embodiment of a volatile signal memory with a flip-flop,

FIG. 4 a block diagram for a memory matrix field with control electronics, and

FIG. 5 a diagram with time potential curves.

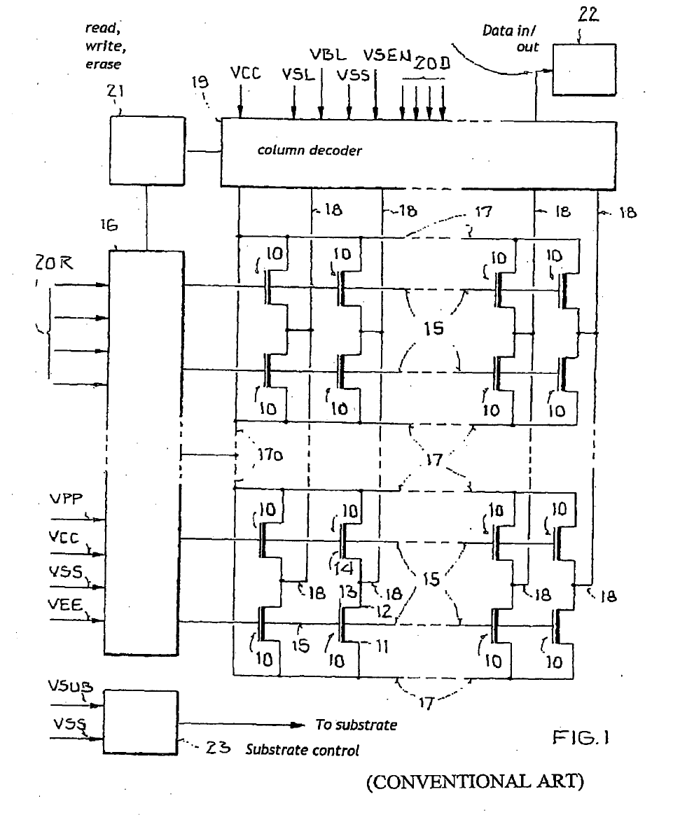

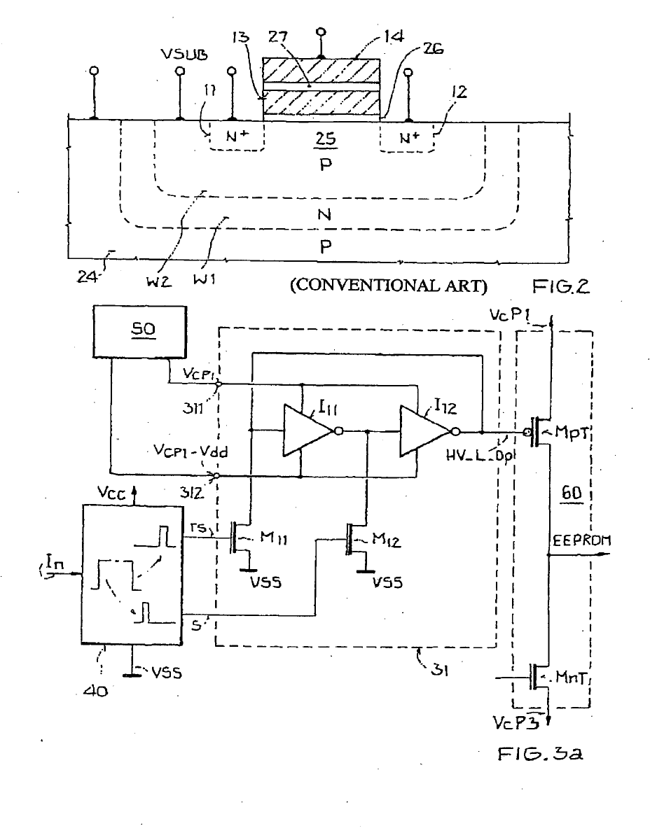

### DETAILED DESCRIPTION

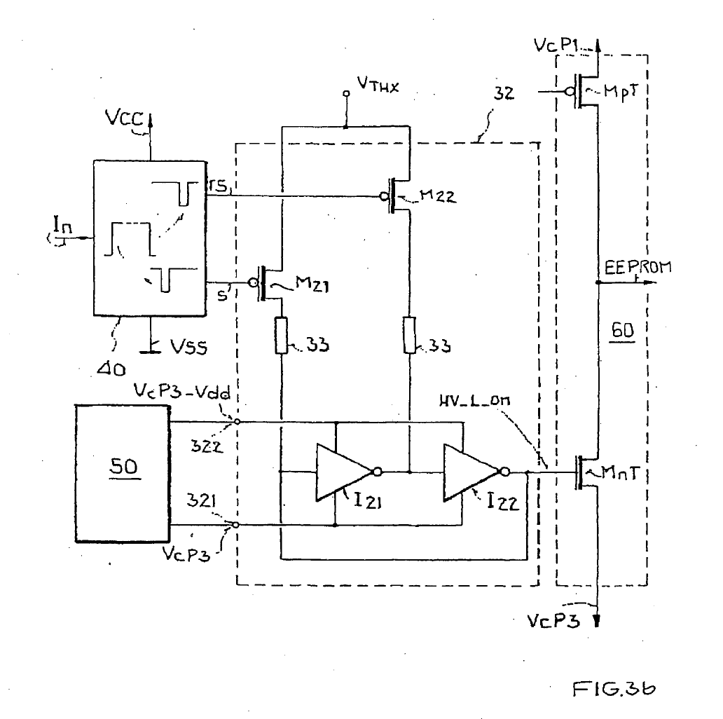

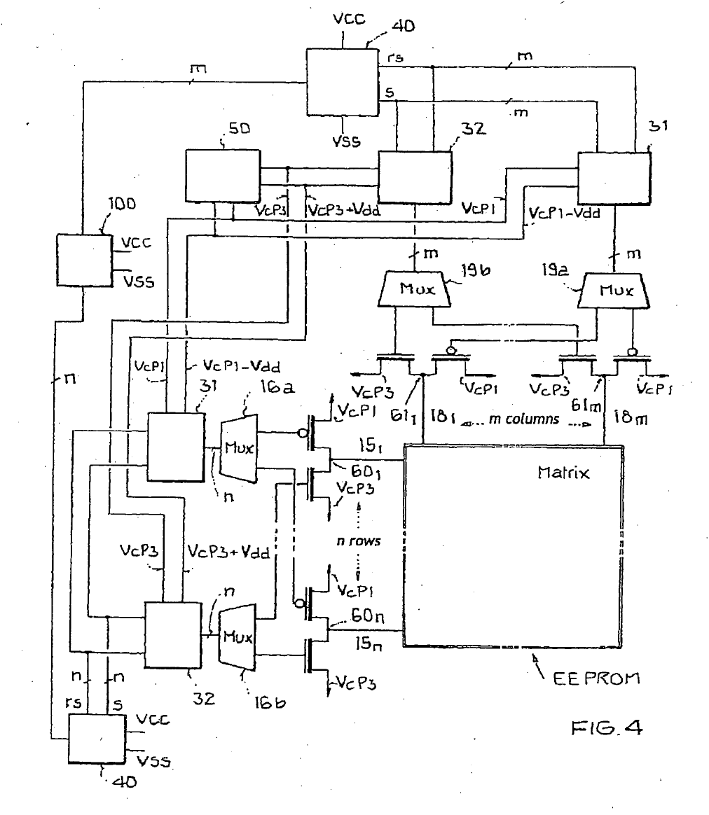

FIG. 3a shows a first embodiment of a static memory of a volatile signal memory 31 and a circuit block 40 for signal conversion. Circuit block 40 is supplied by the logic potentials Vcc and ground Vss. The static memory of volatile signal memory 31, on the contrary, is supplied by the variable potentials VCP1 and VCP1−Vdd. Volatile signal memory 31 has a high-voltage output HV_L_Op for driving a driver transistor M_{pT} of a push-pull stage 60 for programming a matrix EEPROM of an electrically erasable programmable read-only memory or an electrically programmable read-only memory. A decoder 16a, 16b, 19a, 19b can be connected in addition between volatile signal memory 31 and push-pull stage 60, as will be described in greater detail for FIG. 4.

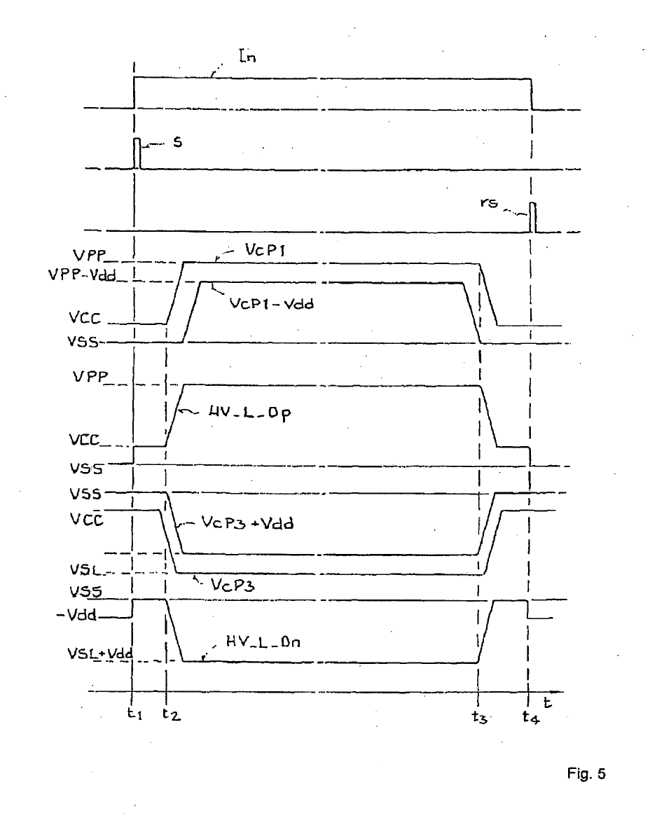

The edges of the logic signals, which are applied at input Iₙ of circuit block 40, are converted to short pulses in circuit block 40. These pulses function to set or reset the static memory from inverters I11 and I12, which can also be designated as latch I11, I12. To reset latch I11, I12, a first output rs of circuit block 40 is connected to a gate of a first NMOS transistor M11, whose drain-source breakdown voltage is designed for the maximum arising voltage (VPP, FIG. 5). A second output s of circuit block 40 is connected to a gate of a second NMOS transistor M12, whose drain-source breakdown voltage is also designed for the maximum arising voltage (VPP, FIG. 5). The pulses have the effect that the current drain from charge pump 50 occurs only for the duration of the pulse, so that charge pump 50 advantageously requires a reduced chip area.

An input of first inverter I11 of the latch is connected to a drain of first transistor M11. An input of second inverter I12 of the latch is connected to a drain of second transistor M12. The short pulses at the outputs rs and s have the effect that first transistor M11 or second transistor M12 is placed in the conducting state only for the duration of the specific pulse. With this conduction by the specific transistor M11 or M12, the input of the specific inverter I11 or I12 is briefly connected to ground Vss, so that latch I11, I12 is set accordingly to a high value or a low value as the output value at output HV_L_Op. During this process, the supply voltage VCP1 is too low, however, to program the EEPROM with a bit value.

Circuit block 40 for converting the logic signals is supplied with a logic potential Vcc and a ground potential Vss to form a logic voltage. Here, logic one (high) corresponds to the logic potential Vcc and logic zero (low) to the ground potential Vss. The foregoing described setting or resetting of latch I11, I12 occurs while latch inverters 11 and I12 are also supplied with supply potentials, which approach the potentials Vcc and ground Vss, so that preferably VCP1≈Vcc and VCP1−Vdd≈Vss. Latch I11, I12 is supplied via a terminal 311 with the supply potential VCP1 and via terminal 312 with the supply potential VCP1−Vdd. Therefore, a supply voltage of
VCP1−(VCP1−Vdd)=Vdd
declines across these two terminals 311 and 312. Advantageously, the supply voltage Vdd approaches the logic voltage in circuit block 40; here, it need only be assured that conduction by transistors M12 or M11 causes as setting or resetting of the static memory.

The supply potentials VCP1 and VCP1−Vdd are generated by a charge pump 50, which is known per se and is shown as a block in FIG. 3a. Said supply potentials VCP1 and VCP1−Vdd are variable by charge pump 50 and/or settable event- and/or time-dependent.

While the high-voltage switching transistors M11 and M12 are conducting, a current is removed from charge pump 50. The currents thereby flow through the high voltage switching transistors M11 and M12 only during the switching process of the specific transistor M11 or M12. Because these transistors M11 and M12 are conducting only during the short pulses, the current drain from charge pump 50 is significantly reduced.

After there no longer is a pulse at a gate of one of the transistors M11 and M12, latch I11, I12 is quasi-floating. The binary value set by the pulses is stored in latch I11, I12, however. Then, the supply potential VCP1 and in parallel the supply potential VCP1−Vdd are increased to a potential necessary for programming the matrix EEPROM (VPP, FIG. 5) by charge pump 50. The binary value stored in latch I11, I12 is now available at a high potential level and can assume a programming potential value
VCP1≈VPP
or a potential smaller by the voltage Vdd than the programming potential
VCP1−Vdd≈VPP−Vdd (FIG. 5),
both of which are different from the logic potentials Vcc and (ground) Vss.

If the output value here corresponds to VCP1≈VPP, this potential value is applied at a gate of the driver transistor M_{pT} of push-pull stage 60. Because its source is also connected to this potential value VCP1, it blocks transistor M_{pT}. If the output value, on the other hand, corresponds to VCP1−Vdd, the voltage at the gate of transistor M_{pT} is lower by the amount Vdd, so that transistor M_{pT} conducts and switches the potential VCP1≈VPP to a cell of the nonvolatile memory matrix EEPROM.

In FIG. 3a, the push-pull stage 60 high-side transistor M_{pT}, with which depending on the stored value the programming potential VPP (FIG. 5) is switched to the cell of the matrix EEPROM, is driven directly by latch I11, I12 by means of the potentials VCP1=VPP or VCP1−Vdd=VPP−Vdd. If the second (negative) programming potential is the ground-potential Vss, the low-side transistor M_{nT} of push-pull stage 60 is driven directly by the logic potentials Vcc and (ground) Vss (not shown in FIG. 3a).

If the second programming potential is not ground Vss, but a second more negative potential (VSL, FIG. 5) is needed for programming, the circuit is supplemented by a negative complementary branch 32. This negative complementary branch 32 is shown as a block diagram in FIG. 3b. The volatile signal memory therefore has complementary subcircuits 31 and 32.

Therefore, a volatile signal memory 32 is shown which is supplied by the variable potentials VCP3 and VCP3+Vdd. The same circuit block 40 is also provided with pulses at the outputs r and rs. These are connected with one gate each of a high-voltage PMOS transistor M21 or M22. Two current limiters 33 in the form of constant current sources or resistors limit the pulse currents. Circuit block 40 is supplied by the supply potentials Vcc and (ground) Vss. The static memory of volatile signal memory 32, on the contrary, is supplied by the variable potentials VCP3 at the first supply terminal 321 and VCP3−Vdd at supply terminal 322. Volatile signal memory 32 has a high-voltage output HV_L_On for driving a driver transistor M_{nT} of a push-pull stage 60 for programming the matrix EEPROM of the electrically erasable programmable read-only memory or the electrically programmable read-only memory.

The source terminals of PMOS-transistors M21 and M22 are connected to a potential VTHX, which is higher by a threshold voltage of the PMOS transistors M21, M22 than ground Vss, so that a low pulse, whose value corresponds to the ground potential Vss, is conducted at one of the outputs r or rs of the connected transistor M21 or M22. A conduction by one of the transistors M21 or M22 in turn causes a setting of a latch comprising inverters I21 and I22.

After lowering the potentials VCP3 and VCP3+Vdd to
VCP3≈VSL
and
VCP3+Vdd≈VSL+Vdd,
latch I21, I22 generates a corresponding high-voltage-output signal at output HV_L_On.

During the setting of latch I21, I22, a third supply potential VCP3 is applied at the first terminal, whereby
VCP3≈0 V (ground)−Vdd=−Vdd.

The fourth supply potential is set in the meantime to
VCP3+Vdd≈0 V (ground).

Thus, a supply voltage of Vdd drops across both inverters 121 and 122 of the latch. For programming the matrix EEPROM, the potential VCP3 is reduced to a negative programming potential (VSL, FIG. 5).

The time-related changes in the potentials VCP1, VCP1−Vdd, VCP3, and VCP3+Vdd are illustrated in greater detail in FIG. 5. At input Iₙ of circuit block 40, the input signal at time t1 changes with a positive edge from the first, lower logic potential Vss to the second, upper logic potential Vcc. This produces almost simultaneously a pulse at output s. By means of the pulse at output s, both latch I11, I12 of signal memory 31 in FIG. 3a is set by conduction by the NMOS transistor M12 and latch 121, 122 of volatile signal memory 32 by conduction by PMOS transistor M21 of FIG. 3b. Accordingly, the output value at output HV_L_Op changes from Vss to Vcc and the output value at output HV_L_On from −Vdd to Vss.

To achieve the programming mode, supply potentials VCP1, VCP1−Vdd, VCP3, and VCP3+Vdd are changed by charge pump 50 (as a block in FIG. 4). Supply potentials VCP1 and VCP1−Vdd are increased until VCP1 achieves a positive programming potential of VPP. In this way, the supply potential VCP1−Vdd can also achieve or exceed the potential VPP−Vdd. The negative supply potential VCP3 is reduced simultaneously until it achieves a negative programming potential VSL. The supply potential VCP3+Vdd achieves substantially simultaneously the potential VSL+Vdd.

Therefore, the output potential at output HV_L_Op as of time t2 increases from logic potential Vcc to positive programming potential VPP. The output potential at output HV_L_On decreases as of time t2 from logic potential Vss to negative programming potential VSL+Vdd. This potential VSL+Vdd switches, for example, the NMOS transistor M_{nT} of the post-connected push-pull stage 60, as is shown in FIG. 4. The programming process is completed by time t3, so that the output potential at output HV_L_Op as of time t3 is lowered from positive programming potential VPP to logic potential Vcc. The output potential at output HV_L_On increases as of time t3 from negative programming potential VSL+Vdd to logic potential Vss. These changes in the output potentials are accordingly controlled by charge pump 50 with a change in the supply potentials VCP1, VCP1−Vdd, VCP3, and VCP3+Vdd.

At time t4, new binary values are stored in the signal memory. In the case shown in FIG. 5, the binary value at the input Iₙ is again changed and a negative edge generates a pulse at output rs, which causes a change in the logic potentials Vcc to Vss at output HV_L_Op and −Vss to −Vdd at output HV_L_On.

FIG. 4 shows a block diagram of a memory device. Logic 100, for example, a controller, is connected by an n-bit-wide parallel bus to a number of n pulse formers 40. The outputs r and rs of all n pulse formers are connected by another n-bit-wide parallel bus to a number of n static memories of volatile signal memory 31 and to a number of n static memories of volatile signal memory 32. All outputs of the n static memory of signal memory 31 and 32 are each connected by an n-bit-wide parallel bus to decoders 16a and 16b which drive the n rows of the matrix EEPROM by push-pull stages 60₁ to 60ₙ. A corresponding structure is provided for the m columns by decoders 19a and 19b. It is especially advantageous here that decoders 16a, 16b or 19a, 19b are connected after signal memory 31, 32 and before push-pull stages 60₁ to 60ₙ and 60₁ to 60ₘ. Substantial chip area can be saved by this means.

Volatile signal memory 31, 32 is connected to charge pump 50, which generates the supply potentials VCP1, VCP1−Vdd, VCP3, and VCP3+Vdd. Of course, the invention is not limited to the structure shown in FIG. 4, but is especially advantageous in the exemplary embodiment shown therein. The design of signal memory 31, 32 according to the exemplary embodiments of FIGS. 3a and 3b has the advantage that only one type of an NMOS transistor and a PMOS transistor is required, because a programming voltage not dependent on the programming potentials VSL or VPP declines across their gate oxide. Transistors with an additionally thick gate oxide, necessary for this, are not required.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A memory device comprising:
a nonvolatile memory matrix;
a driver for programming the memory matrix, the driver being connected to the memory matrix to drive a programming potential;
a volatile signal memory to drive the driver; and
a changeable voltage source, which is connected to the volatile signal memory to adjust an output voltage of the volatile signal memory for programming the nonvolatile memory matrix.

2. The memory device according to claim 1, wherein the changeable voltage source is operably connected to a number of supply terminals of the signal memory.

3. The memory device according to claim 1, wherein the changeable voltage source is operably connected to a number of supply terminals of the driver.

4. The memory device according to claim 1, wherein the volatile signal memory has a static memory and/or a flip-flop.

5. The memory device according to claim 1, wherein the driver has a push-pull stage.

6. The memory device according to claim 1, wherein a decoder is operably connected between the volatile signal memory and the driver.

7. The memory device according to claim 6, wherein the changeable voltage source is operably connected to a number of supply terminals of the decoder.

8. The memory device according to claim 1, wherein the changeable voltage source is operably connected to a first supply voltage terminal of the volatile signal memory to apply a first, changeable supply potential and to a second supply voltage terminal of the volatile signal memory to apply a second, changeable supply potential.

9. The memory device according to claim 8, wherein the changeable voltage source is designed in such a way that the second, changeable supply potential differs by a fixed differential voltage from the first, changeable supply potential.

10. The memory device according to claim 1, wherein the changeable voltage source is operably connected to a third supply voltage terminal of the volatile signal memory to apply a third, changeable supply potential and to a fourth supply voltage terminal of the volatile signal memory to apply a fourth, changeable supply potential.

11. The memory device according to claim 10, wherein the changeable voltage source is designed in such a way that the fourth, changeable supply potential differs by a fixed differential voltage from the third, changeable supply potential.

12. The memory device according to claim 8, wherein the changeable voltage source applies the first supply potential and the third supply potential at the driver.

13. The memory device according to claim 6, wherein the changeable voltage source applies the first supply potential and the third supply potential at the decoder.

14. The memory device according to claim 1, wherein the changeable voltage source has at least one controllable charge pump, preferably two controllable charge pumps with different pump voltages.

15. The memory device according to claim 1, further comprising a limiter for limiting the current drain from the changeable voltage source.

16. The memory device according to claim 15 wherein the limiter for limiting the current drain has two transistors, which are connected to a pulse-forming circuit for driving, and the pulse-forming circuit is designed in such a way that the two transistors are controllable exclusively for writing the volatile signal memory in the conducting state.

17. The memory device according to claim 1, wherein the volatile signal memory has a number of inputs, which are connected to a pulse-forming circuit similar to a pulse gate to generate a pulse from a bit value.

18. The memory device according to claim 1, wherein the volatile signal memory has a first transistor for setting and a second transistor for resetting a static memory, whereby a first control input of the first transistor is connected to a first input and a second control input of the second transistor to a second input.

19. A method for programming a nonvolatile memory matrix, wherein for programming, a programming potential different from the logic potentials is applied, the method comprising:
reading, for programming a bit value, into a volatile signal memory as an H level or an L level; and
increasing all supply potentials of the signal memory by an offset voltage in such a way that the H level or the L level approaches the desired programming potential.
